(19) United States
(12) Patent Application Publication
(10) Pub. No.: US 2021/0050320 A1
(43) Pub. Date: Feb. 18, 2021

(54) PACKAGE STRUCTURE FOR POWER DEVICE

(71) Applicant: ACTRON TECHNOLOGY CORPORATION, Taoyuan City (TW)

(72) Inventors: Hsin-Chang Tsai, Taoyuan City (TW); Ching-Wen Liu, Taoyuan City (TW)

(73) Assignee: ACTRON TECHNOLOGY CORPORATION, Taoyuan City (TW)

(21) Appl. No.: 16/671,197

(22) Filed: Nov. 1, 2019

(30) Foreign Application Priority Data
Aug. 14, 2019 (TW) 108128918

(51) Int. Cl. H01L 23/00; H01L 25/07; H01L 25/18; H01L 23/498; H01L 23/373

(52) U.S. Cl. CPC H01L 24/40; H01L 25/072; H01L 25/18; H01L 23/49838; H01L 24/37; H01L 23/3735; H01L 2224/73255; H01L 2224/37124; H01L 2224/37147; H01L 2224/37193; H01L 2224/40137; H01L 2224/40225; H01L 24/73

(57) ABSTRACT

A package structure for power devices includes a heat dissipation insulating substrate, a plurality of power devices, at least one conductive clip, and a heat dissipation baseplate. The heat dissipation insulating substrate has a first surface and a second surface opposite thereto, and the power devices form a bridge circuit topology and are disposed on the first surface, wherein active regions of at least one of the power devices are flip-chip bonded to the first surface. The conductive clip is configured to electrically connect at least one of the power devices to the first surface, and the heat dissipation baseplate is disposed at the second surface of the heat dissipation insulating substrate.

### CROSS-REFERENCE TO RELATED APPLICATION

This application claims the priority benefit of Taiwan application serial no. 108128918, filed on Aug. 14, 2019. The entirety of the above-mentioned patent application is hereby incorporated by reference herein and made a part of this specification.

### BACKGROUND OF THE INVENTION

### Field of the Invention

The disclosure relates to a package structure, and particularly, to a package structure for power devices.

### Description of Related Art

At present, a power module is a main core apparatus for electric energy conversion in various products, inside which power devices are packaged. At early stage, an aluminum (Al) metal wire is used as a connection line between chips in the power module, and the excessive parasitic inductance and parasitic impedance cause high electric power conversion loss and uneven current distribution.

### SUMMARY OF THE INVENTION

The invention provides a package structure for power devices, which can solve the problem of electric power conversion loss caused by the excessive parasitic effect of the traditional power module.

The invention further provides a package structure for power devices, which can reduce the stray inductance and thermal resistance of the power module.

The package structure for power devices of the invention includes a heat dissipation insulating substrate, a plurality of power devices, at least one conductive clip and a heat dissipation baseplate. The heat dissipation insulating substrate has a first surface and a second surface opposite thereto. The power devices form a bridge circuit topology and are disposed on the first surface, wherein active regions of at least one of the power devices are flip-chip bonded to the first surface. The conductive clip is configured to electrically connect at least one of the power devices to the first surface. The heat dissipation baseplate is disposed at the second surface of the heat dissipation insulating substrate.

In an embodiment of the invention, one conductive clip electrically connects one or more of the power devices to the heat dissipation insulating substrate and is disposed at an opposite side of the power device opposite to a side where the power device is bonded to the heat dissipation insulating substrate.

In an embodiment of the invention, a material of the conductive clip includes aluminium, copper or graphite.

In an embodiment of the invention, the plurality of power devices include, for example, vertical power devices, active regions of the vertical power devices are flip-chip bonded to the first surface, and the at least one conductive clip electrically connects non-active regions of the vertical power devices to the first surface.

In an embodiment of the invention, the heat dissipation insulating substrate includes a direct bonded copper (DBC) ceramic substrate, a direct plating copper (DPC) ceramic substrate, an insulating metal substrate (IMS) or a printed circuit board (PCB).

In an embodiment of the invention, the heat dissipation insulating substrate has a patterned circuit which contains a plurality of electrical functions and is electrically connected with the at least one conductive clip, and the patterned circuit is electrically connected with the plurality of power devices.

In an embodiment of the invention, one conductive clip may connect the patterned circuit of different electrical functions.

In an embodiment of the invention, the second surface of the heat dissipation insulating substrate is monolithically formed with the heat dissipation baseplate or thermally contacts with the heat dissipation baseplate.

Another package structure for power devices of the invention includes: a heat dissipation insulating substrate, a plurality of vertical power devices and at least one conductive clip. The plurality of vertical power devices form a bridge circuit topology, and active regions of at least one of the vertical power devices are flip-chip bonded to the heat dissipation insulating substrate. The conductive clip electrically connects non-active regions of the vertical power devices, which are flip-chip bonded to the heat dissipation insulating substrate, to the heat dissipation insulating substrate.

In another embodiment of the invention, the heat dissipation insulating substrate has a patterned circuit which contains a plurality of electrical functions and is electrically connected with the at least one conductive clip, and the patterned circuit is electrically connected with the plurality of vertical power devices.

In another embodiment of the invention, one conductive clip connects the patterned circuit of different electrical functions.

In another embodiment of the invention, the package structure for power devices further includes a heat dissipation baseplate disposed at another surface of the heat dissipation insulating substrate other than a surface where the heat dissipation insulating substrate is bonded to the plurality of vertical power devices.

In another embodiment of the invention, the heat dissipation insulating substrate is monolithically formed with the heat dissipation baseplate or thermally contacts with the heat dissipation baseplate.

Based on the above, the package structure for power devices of the invention is a connection configuration where the power device is directly flip-chip bonded to the heat dissipation substrate, and the conductive clip is used to replace the aluminium metal line as a circuit, which achieves the effects of reducing the stray inductance and thermal resistance of the power module by virtue of low parasitic impedance and parasitic inductance of the heat dissipation substrate and the conductive clip, so as to reduce the electrical power conversion loss and more evenly distribute the current.

In order to make the aforementioned and other objectives and advantages of the invention comprehensible, embodiments accompanied with figures are described in detail below.

### BRIEF DESCRIPTION OF THE DRAWINGS

FIG. 1 is a sectional view of a package structure for power devices according to a first embodiment of the invention.

FIG. 2 is a sectional view of another package structure for power devices according to the first embodiment.

FIG. 3 is a sectional view of a package structure for power devices according to a second embodiment of the invention.

FIG. 4A is a plan view of a package structure for power devices constituting a half bridge circuit according to the first embodiment.

FIG. 4B is a circuit diagram of a phase-different half bridge circuit topology device composed of three of the structure shown in FIG. 4A.

FIG. 4C is an electric circuit diagram of a circuit in FIG. 4B.

FIG. 5 is a half bridge circuit diagram.

### DESCRIPTION OF THE EMBODIMENTS

Many different implementations or examples are provided by the following disclosed content to implement different features of the invention. Certainly, these embodiments are only examples and are not intended to limit the scope and application of the invention. In addition, the relative thicknesses and positions of components, films, or regions may be reduced or enlarged for clarity. In addition, same or like reference numerals are used in the accompanying drawings to indicate same or like elements or features. Details of reference numerals that appear in one drawing may be omitted in the description of the following drawings.

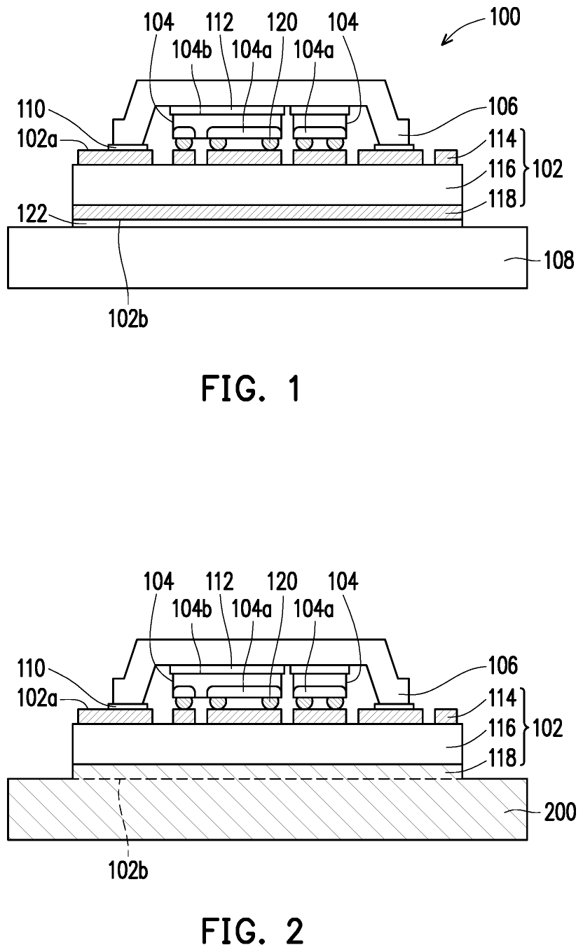

FIG. 1 is a sectional view of a package structure for power devices according to a first embodiment of the invention.

Referring to FIG. 1, a package structure 100 for power devices of the present embodiment includes a heat dissipation insulating substrate 102, a plurality of power devices 104, at least one conductive clip 106 and a heat dissipation baseplate 108. The heat dissipation insulating substrate 102 has a first surface 102a and a second surface 102b opposite thereto. The power devices 104 form a bridge circuit topology (including half bridge or full bridge circuit topology) and are disposed on the first surface 102a, wherein active regions 104a of at least one of the power devices 104 are flip-chip bonded to the first surface 102a. In one embodiment, the power device 104 is, for example, a vertical power device, and therefore the active regions (namely 104a) of the vertical power devices are flip-chip bonded to the first surface 102a. The heat dissipation insulating substrate 102 is, for example, a direct bonded copper (DBC) ceramic substrate, a direct plating copper (DPC) ceramic substrate, an insulating metal substrate (IMS) or a printed circuit board (PCB).

In the first embodiment, the conductive clip 106 is configured to electrically connect at least one of the power devices 104 with the first surface 102a, wherein the material of the conductive clip 106 is, for example, aluminium, copper or graphite. Furthermore, one conductive clip 106 may electrically connect a plurality of power devices 104 to the heat dissipation insulating substrate 102 and is disposed at an opposite side 104b of the power device 104 opposite to a side where the power device 104 is bonded to the heat dissipation insulating substrate 102. However, the invention is not limited thereto, one conductive clip 106 may also only electrically connect one power device 104 to the heat dissipation insulating substrate 102. In one embodiment, if the power device 104 is a vertical power device, a part of the conductive clip 106 may electrically connect the non-active regions of the vertical power devices, and the other part of the conductive clip 106 may electrically connect the first surface 102a. In addition, mutual electric connection may be formed between the first surface 102a and the conductive clip 106 by virtue of a first conductive connection layer 110, and mutual electric connection may be formed between the power device 104 and the conductive clip 106 by virtue of a second conductive connection layer 112, but the invention is not limited thereto. The first conductive connection layer 110 and the second conductive connection layer 112 are, for example, sintered silver layers or other conductive connection layers.

Referring again to FIG. 1, the heat dissipation insulating substrate 102 has a patterned circuit 114, and the patterned circuit 114 is formed on an insulating material board 116. The second surface 102b of the heat dissipation insulating substrate 102 may be provided with an entire lower circuit layer 118. For example, solder joints 120 are formed on pads (not shown) of each power device 104, and the solder joints 120 are configured to right face the patterned circuit 114 of the heat dissipation insulating substrate 102 by utilizing a flip-chip bonding technology to realize the connection of the power device 104 and the heat dissipation insulating substrate 102. The patterned circuit 114 may include a plurality of electrical functions and is electrically connected with the conductive clip 106, and the patterned circuit 114 is electrically connected with the power device 104. In one embodiment, one conductive clip 106 may connect the patterned circuit 114 of different electrical functions.

The heat dissipation baseplate 108 is disposed at the second surface 102b of the heat dissipation insulating substrate 102, and may be mutually electrically connected via a third conducive connection layer 122, wherein the third conductive connection layer 122 is, for example, a sintered silver layer or other conductive connection layers. However, the invention is not limited thereto.

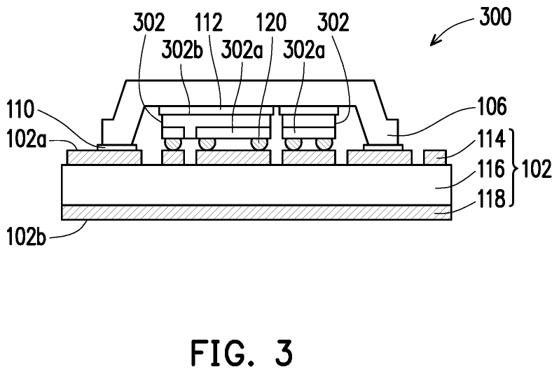

The second surface 102b of the heat dissipation insulating substrate 102 may also be monolithically formed with a heat dissipation baseplate 200 or thermally contact with the heat dissipation baseplate 200, as shown in FIG. 2. That is to say, the heat dissipation baseplate 200 and the lower circuit layer 118 of the heat dissipation insulating substrate 102 may be in a monolithically formed or thermal contact configuration.

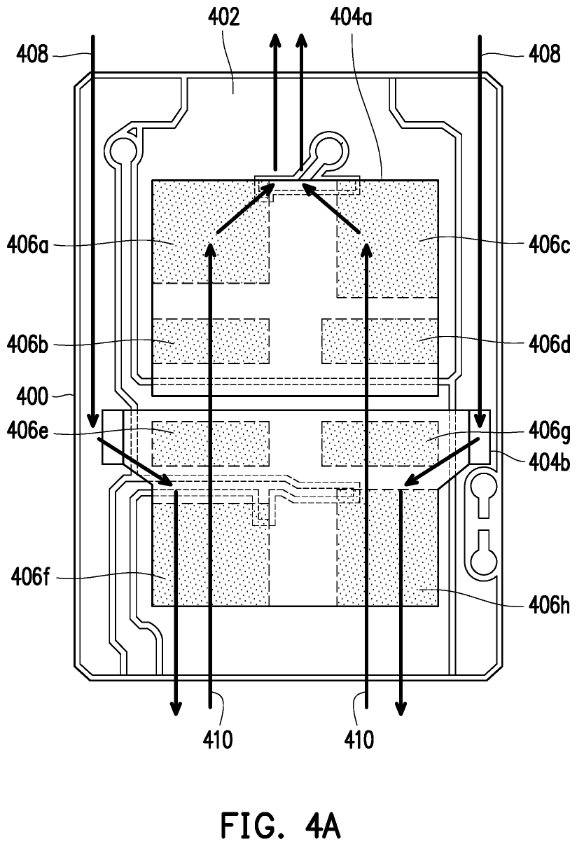

FIG. 3 is a sectional view of a package structure for power devices according to a second embodiment of the invention, wherein component symbols and parts of the content of the previous embodiment are used, in which the same component symbols are used to represent the same or similar components, and the description of the same technical content is omitted. Reference may be made to the preceding embodiment for descriptions of the omitted parts, which will not be repeated in the present embodiment.

Referring to FIG. 3, a package structure 300 for power devices of the present embodiment includes a heat dissipation insulating substrate 102, a plurality of vertical power devices 302 and at least one conductive clip 106. The plurality of vertical power devices 302 form a bridge circuit topology, and active regions 302a of at least one of the vertical power devices 302 are flip-chip bonded to the heat dissipation insulating substrate 102. The conductive clip 106 electrically connects non-active regions 302b of the vertical power devices 302, which are flip-chip bonded to the heat dissipation insulating substrate 102, to the heat dissipation insulating substrate 102. In one embodiment, the package structure 300 for power devices may also include a heat dissipation baseplate (not shown) disposed at another surface of the heat dissipation insulating substrate 102 other than a surface where the heat dissipation insulating substrate 102 is bonded to the vertical power device 302. In another embodiment, the heat dissipation insulating substrate 102 may be monolithically formed with the heat dissipation baseplate or thermally contact with the heat dissipation baseplate (not shown).

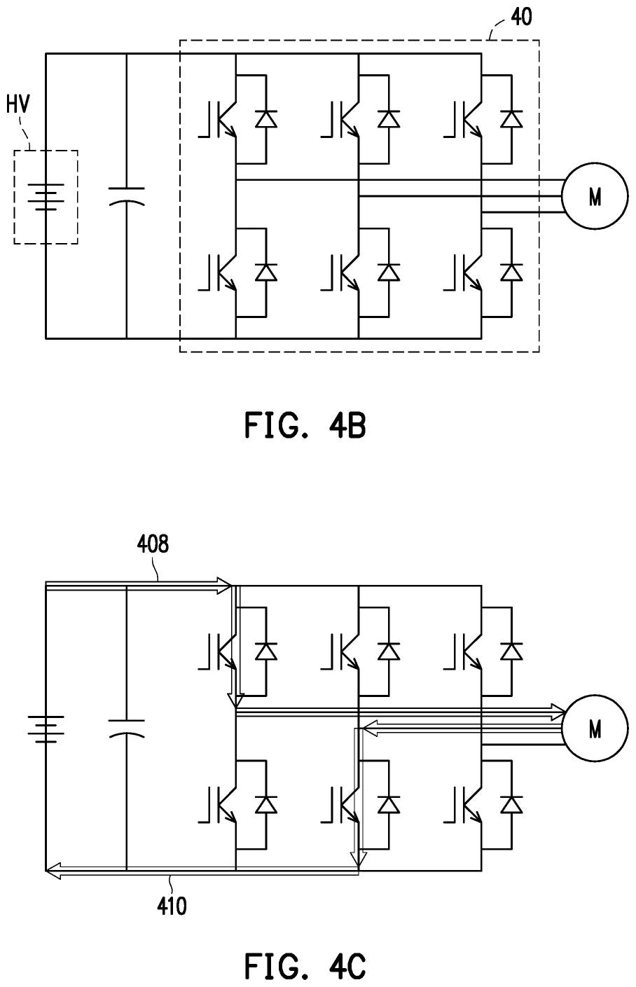

FIG. 4A is a plan view of a package structure for power devices constituting a half bridge circuit according to the first embodiment.

Referring to FIG. 4A, a heat dissipation insulating substrate 400 has a patterned circuit 402. The patterned circuit 402 contains a plurality of electrical functions and is electrically connected with a plurality of conductive clips 404a and 404b, and the patterned circuit 402 is respectively electrically connected with vertical power devices 406a, 406b, 406c, 406d, 406e, 406f, 406g and 406h. That is to say, if FIG. 4A is taken as an example, one conductive clip 404a may connect the patterned circuit 402 of different electrical functions to four vertical power devices 406a, 406b, 406c and 406d; another conductive clip 404b may connect the patterned circuit 402 of different electrical functions to another four vertical power devices 406e, 406f, 406g and 406h. Although the vertical power devices 406a to 406h in FIG. 4A are shown in rectangular frames, it should be known that the power devices contained in the regions of the rectangular frames may be the same or different, for example, a power device set of combination of an insulated gate bipolar transistor (IGBT) and a fast recovery diode (FRD). The heat dissipation baseplate is not shown in FIG. 4A, but it should be known that the heat dissipation baseplate is disposed at the back surface of the heat dissipation insulating substrate 400.

FIG. 4B is a circuit diagram of a phase-different half bridge circuit topology device composed of three of the structure shown in FIG. 4A. FIG. 4C is an electric circuit diagram of a circuit in FIG. 4B.

In FIG. 4B, an inverter 40 is disposed in a path where a high-voltage battery HV supplies electricity to a motor M, the circuit thereof includes a half-bridge circuit topology having three different phases, and the half-bridge circuit topology of each phase may use a structure of FIG. 4A. Thus, when the high-voltage battery HV supplies electricity to the motor M, the current circuit thereof flows to the motor M via a high side circuit 408 of a specific phase in FIG. 4A and FIG. 4C, then flows from the motor M to a low side circuit 410 of another specific phase, and finally flows to the high-voltage battery HV, so as to form an entire circuit.

The above circuits are only one embodiment of the package structure for power devices of the invention and are not intended to limit the application scope of the invention.

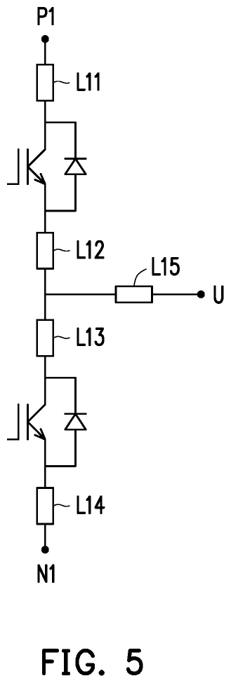

If the half-bridge circuit of FIG. 5 is taken as an example, the parasitic inductance L_{sCE}=L11+L12+L13+L14. Therefore, the parasitic inductance L_{sCE} of the traditional half-bridge circuit using wire bonding is about 5.55 nH, while the parasitic inductance L_{sCE} of the half-bridge circuit of the invention using the conductive clip (such as 106 of FIG. 1) combined with the flip-chip bonding technology is 4.45 nH. Therefore, the package structure for power devices of the invention may reduce 20% in the aspect of parasitic inductance. Because the voltage surge ΔV=L(di/dt), if the parasitic inductance decreases, the voltage surge will naturally decrease. Therefore, the package structure for power devices of the invention can also reduce the voltage surge.

In addition, because the area and thermal conductivity coefficient of the conductive clip (such as a copper clip) are both higher than those of traditional aluminium metal wires for wire bonding, the thermal resistance (R_{JF}) can be reduced from 0.14° C./W in the case of the traditional wiring to 0.10° C./W in the case of using the conductive clip, wherein the thermal resistance drop is as much as 30%.

Based on the above, according to the invention, the power devices are directly bonded to the heat dissipation insulating substrate through the flip-chip bonding technology, and the conductive clip is used as the connection configuration of the circuit. Therefore, by virtue of the properties of the heat dissipation insulating substrate and the conductive clip, such as low parasitic impedance and low parasitic inductance, the stray inductance and the thermal resistance of the power module can be reduced, which further reduces the electric power conversion loss, more evenly distributes the current, and decreases the voltage surge.

Although the invention is described with reference to the above embodiments, the embodiments are not intended to limit the invention. A person of ordinary skill in the art may make variations and modifications without departing from the spirit and scope of the invention. Therefore, the protection scope of the invention should be subject to the appended claims.

What is claimed is:

1. A package structure for power devices, comprising:
a heat dissipation insulating substrate, comprising a first surface and a second surface opposite thereto;
a plurality of power devices forming a bridge circuit topology and disposed on the first surface, wherein active regions of at least one of the power devices are flip-chip bonded to the first surface;
at least one conductive clip, configured to electrically connect at least one of the power devices to the first surface; and
a heat dissipation baseplate, disposed at the second surface of the heat dissipation insulating substrate.

2. The package structure for power devices according to claim 1, wherein one conductive clip electrically connects one or more of the power devices to the heat dissipation insulating substrate and is disposed at an opposite side of the power device opposite to a side where the power device is bonded to the heat dissipation insulating substrate.

3. The package structure for power devices according to claim 1, wherein a material of the conductive clip comprises aluminium, copper or graphite.

4. The package structure for power devices according to claim 1, wherein the plurality of power devices comprise vertical power devices, active regions of the vertical power devices are flip-chip bonded to the first surface, and the at least one conductive clip electrically connects non-active regions of the vertical power devices to the first surface.

5. The package structure for power devices according to claim 1, wherein the heat dissipation insulating substrate comprises a direct bonded copper (DBC) ceramic substrate, a direct plating copper (DPC) ceramic substrate, an insulating metal substrate (IMS) or a printed circuit board (PCB).

6. The package structure for power devices according to claim 1, wherein the heat dissipation insulating substrate comprises a patterned circuit, the patterned circuit contains a plurality of electrical functions and is electrically connected with the at least one conductive clip, and the patterned circuit is electrically connected with the plurality of power devices.

7. The package structure for power devices according to claim 6, wherein one conductive clip connects the patterned circuit of different electrical functions.

8. The package structure for power devices according to claim 1, wherein the second surface of the heat dissipation insulating substrate is monolithically formed with the heat dissipation baseplate or thermally contacts with the heat dissipation baseplate.

9. A package structure for power devices, comprising:
a heat dissipation insulating substrate;
a plurality of vertical power devices forming a bridge circuit topology, wherein active regions of at least one of the vertical power devices are flip-chip bonded to the heat dissipation insulating substrate; and
at least one conductive clip, electrically connecting non-active regions of the vertical power devices, which are flip-chip bonded to the heat dissipation insulating substrate, to the heat dissipation insulating substrate.

10. The package structure for power devices according to claim 9, wherein the heat dissipation insulating substrate comprises a patterned circuit, the patterned circuit contains a plurality of electrical functions and is electrically connected with the at least one conductive clip, and the patterned circuit is electrically connected with the plurality of vertical power devices.

11. The package structure for power devices according to claim 10, wherein one conductive clip connects the patterned circuit of different electrical functions.

12. The package structure for power devices according to claim 9, further comprising a heat dissipation baseplate, disposed at another surface of the heat dissipation insulating substrate other than a surface where the heat dissipation insulating substrate is bonded to the plurality of vertical power devices.

13. The package structure for power devices according to claim 12, wherein the heat dissipation insulating substrate is monolithically formed with the heat dissipation baseplate or thermally contacts with the heat dissipation baseplate.
